(19) United States
(12) Patent Application Publication
(10) Pub. No.: US 2023/0384842 A1
(43) Pub. Date: Nov. 30, 2023

(54) SOCKETED MEMORY ARCHITECTURE PACKAGE AND METHOD

(71) Applicant: Intel Corporation, Santa Clara, CA (US)

(72) Inventors: Siva Prasad Jangili Ganga, Telangana (IN); Shailendra Singh Chauhan, Bengaluru (IN); Abhijith Prabha, Piravom (IN); Geejagaaru Krishnamurthy Sandesh, Bangalore (IN); Santhosh Ap, Bangalore (IN)

(21) Appl. No.: 17/825,558

(22) Filed: May 26, 2022

(51) Int. Cl. G06F 1/18; H05K 7/14; G06F 1/16; H05K 7/20

(52) U.S. Cl. CPC G06F 1/185; H05K 7/1422; G06F 1/1633; H05K 7/2039

(57) ABSTRACT

An electronic system has a printed circuit board and a substrate. The substrate has two sides, a top and bottom. At least one memory unit is connected to the bottom side of the substrate and at least one processor is connected to the top side of the substrate. The memory is connected to the processor with interconnects that pass through the substrate.

### TECHNICAL FIELD

This document pertains generally, but not by way of limitation, to a removable and replaceable memory component for a computer system.

### BACKGROUND

Some computers have replaceable components allowing the user to modify the computer according to their needs. For example, a user may want to switch or modify the factory installed memory with larger memory, or memory with more storage or operating capacity. In such a situation, a user may need to remove a large panel, for example the back or bottom cover, of the computer to gain access to the desired component to be replaced. In such a situation, the user may risk damaging the internal systems when removing the cover or the user may damage other internal components when attempting to replace the component the user desires to replace. Further, when a component is to be replaced, the system may have extra layers of protective materials which, while protecting the system, also increase the dimensions of the internal components.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an illustration of an example of the interior of a computer system.

FIGS. 2a and 2b is an illustration of a substrate in a computer system.

FIG. 3 is an illustration of an example of a removable memory component located in an electronic system.

FIG. 4a is an illustration of an example exploded view from the top of a removable memory system.

FIG. 4b is an illustration of the bottom side of a memory system.

FIG. 5 is an illustration of a cross section of the electronic system.

FIG. 6 is an illustration of an example top side and bottom side of a load plate cooling system.

FIG. 7 is an illustration of an electronic system.

FIG. 8 is an illustration of an example of a cooling system in a computer system.

FIG. 9 is an illustration of a removable cover on the exterior of a computer.

FIG. 10 is an illustration of a system level diagram, depicting an example of an electronic system.

### DETAILED DESCRIPTION

In a computer system there is hardware and components which users may want to replace such as the mainboard, memory, processor, power supply, storage or cooling systems. When replacing such components, users may need to remove significant parts of the computer to access the one piece to be replaced. If significant parts do not need to be replaced, at least whole panels of the computer may still need to be removed to gain access to the small part to be replaced. In a laptop or tablet, gaining access to the computer system usually requires the user to remove the entire bottom panel of the computer itself, if the panel can be removed at all.

Memory is an element of computer hardware which is commonly replaced. If a computer does not have enough memory, computer processes or activity can be hindered as low memory is a common cause of slow performance.

A computer system uses Random Access Memory (RAM) to store memory before the data is processed by the central processing unit (CPU). RAM is the memory unit which temporarily stores data while a chip is being engaged. It does not store data for the long term; instead, it stores data as it is needed for the computer's use. Therefore, as a computer system runs more programs, or more complicated programs, more RAM is used.

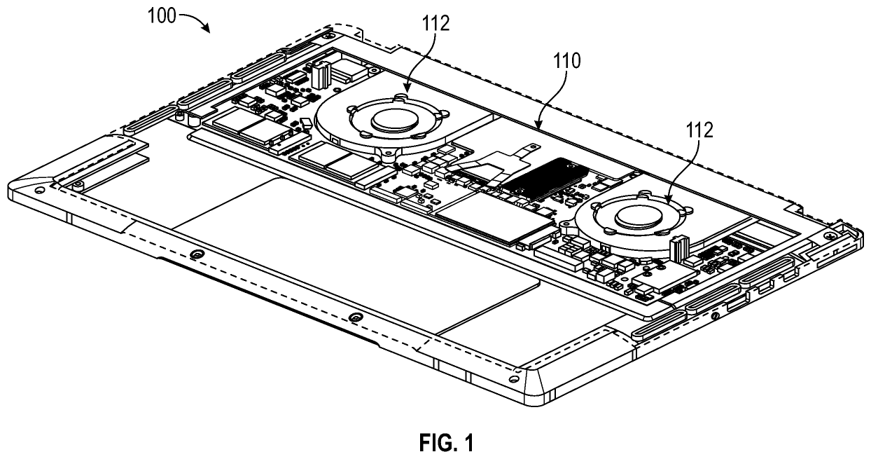

An example computer system 100 is illustrated in FIG. 1. As illustrated in the example computer system 100, there is, for example, an electronic system 110, cooling components 310, such as fans, surface mounted technology and other components necessary for operating the computer.

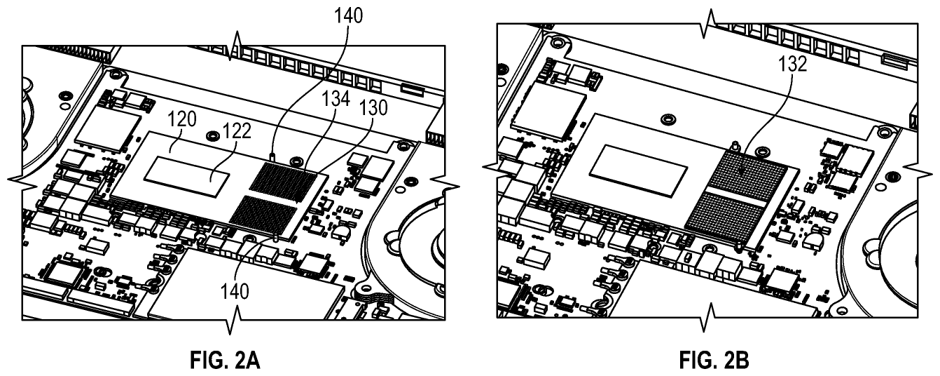

A more detailed view of the layers of the example electronic system 100 is illustrated in FIGS. 2a and 2b. A package or substrate 120 supporting a system on chip (SoC) 122 can be soldered or otherwise coupled to the system at a desired location. On one side of the package 120 is the SoC 122 including any necessary processors, memory, logic and electrical circuits. On another end is the base for a modular or removable memory component, or memory socket footprint 130. The memory socket footprint 130 provides the location for coupling a memory socket 132 to the circuitry or pathways within the package 120. The memory socket 132 is a removable component on the package 120.

The memory socket 132 is sized and shaped according to the desired purpose. In an example memory socket 132, the memory socket footprint 130 can have connection points 134 arranged in a 15 by 21 rectangular pattern for a total of 315 connection points 134. However, any number of connection points 134 can be used. In an example memory socket 132, there are two arrangements of memory socket footprints 130. In an example, each of the memory socket footprints 130 are similar dimensions. A memory socket 132 with two arrangements of memory socket footprints 130 can support two separate removable memory components.

The memory socket 132 is aligned properly on the package 120 using alignment couplings 140. Examples of alignment couplings can be any indicator which is used to properly align the memory socket 132 to the substrate such as visual indications, protrusions, grooves, indentations, etc. The alignment pins 140 are one way of aligning the memory socket 132 properly to the package 120. The memory socket 132 needs to be properly aligned so the individual connection points on the memory socket 132 are aligned with the corresponding connection points 134 on the memory socket footprint 130 on the package 120.

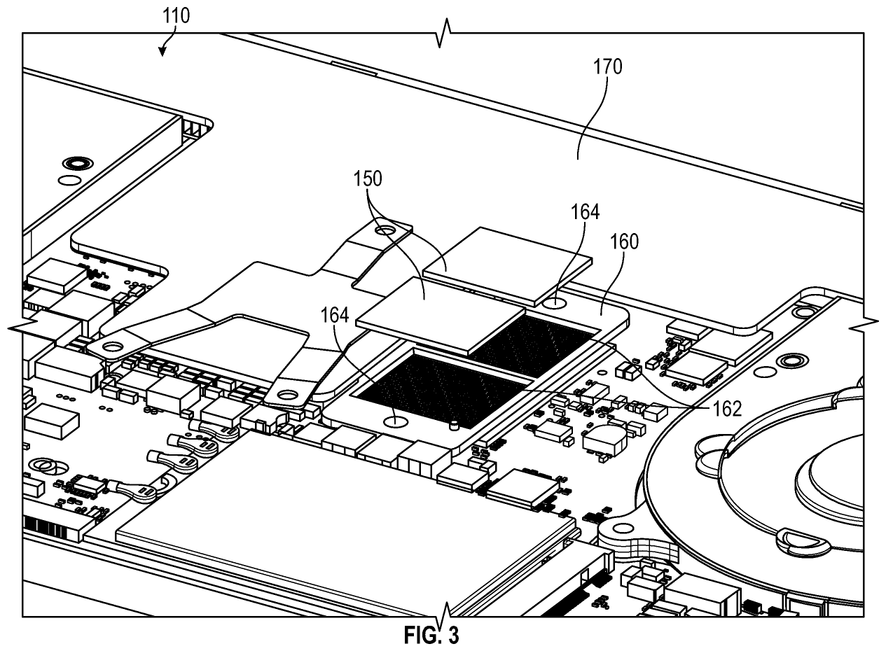

In one example, as shown in FIG. 3, there is at least one removable memory package 150. In the example shown in FIG. 3, there are two removable memory package 150. The removable memory package 150 is coupled with a corresponding memory socket 132. The removable memory package 150 is, for example, RAM that has a memory capacity according to a user's needs or desires. The removable memory package 150 is easily replaceable by a user for example with a small tool or a user's fingers to grasp the removable memory package 150 and thereby remove it from the memory socket 132.

As illustrated in FIG. 3, the removable memory package 150 is supported on the electronic system 110 with a support plate 160. The support plate 160, in the example illustrated in FIG. 3, has at least one slot, opening, or access point, 162. In the example illustrated there can be two slots 162. The at least one slot 162 in the support plate 160 can have a dimension or profile similar to the removable memory package 150. The at least one slot 162 extends through, or is an opening in, the support plate 160 such that the removable memory package 150 can be connected or coupled with the corresponding memory socket 132. In an example, the support plate 160 sandwiches the memory socket 132 on or with the package 120. The support plate 160 can have designated coupling areas 164 to attach the support plate 160 to the electronic system 110. The coupling areas 164 are sized and shaped to support fasteners, such as screws, pegs or similar devices, which are capable of applying a specified load to the support plate 160 to properly couple the support plate 160 to the electronic system 110.

Also illustrated in FIG. 3 is an example vapor chamber 170 disposed on the package 120. The vapor chamber 170 is an example of a heat spreader which can be used for heat flux transformation. The vapor chamber 170 is an example of a heat spreader with a smaller z height. In some examples, a vapor chamber 170 can have a z height of one millimeter or less.

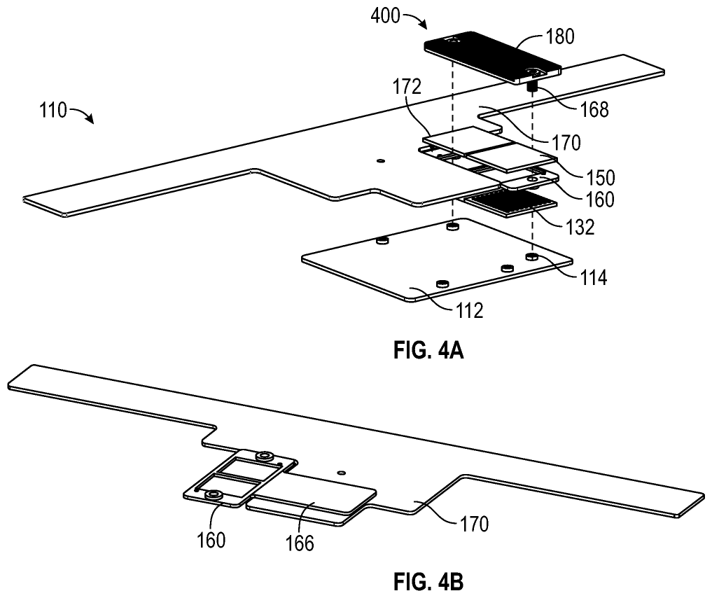

As illustrated in FIGS. 4a and 4b, the support plate 160 is proximate to the vapor chamber 170. The support plate 160, as illustrated in FIG. 4b, has an extension 166 or a thermal dispersion component which can come into contact with the vapor chamber 170. In the example shown, the extension 166 can be made from copper, or a similar conductive material. The extension 166 can be attached to the vapor chamber 170 by soldering or brazing, or another similar way of attaching metal components.

FIG. 4a illustrates an exploded view of an electronic system 110 including a modular memory component 400. As illustrated, the support plate 160 is disposed proximate to the vapor chamber 170. For example, the vapor chamber 170 can be formed such that the support plate 160 fits within a concave 172 in the vapor chamber 170. The support plate 160 can be disposed in any location proximate, and coupled, to the vapor chamber 170 where the vapor chamber 170 does not cover the support plate 160. The support plate 160, and any associated removable memory package 150, should remain accessible to a user in any configuration when coupled with the vapor chamber 170.

In the example exploded view shown in FIG. 4a, the electronic system 110 can also include a back plate 112. The back plate 112 provides at least one termination point 114 to support at least one fastener 168. As illustrated in FIG. 4a, the at least one fastener 168 may pass through a load plate 180, the support plate 160 and terminate at the back plate 112. The back plate 112 can support the package 120 and the support plate 160 when installed in the electronic system 110. The back plate 112 can also provide at least one termination point 114. The termination point 114 can be a mating screw coupling, an interference fitting, or a welding or soldering point, or any other structure to aid in coupling the load plate 180, the support plate 160, the package 120 with the back plate 112.

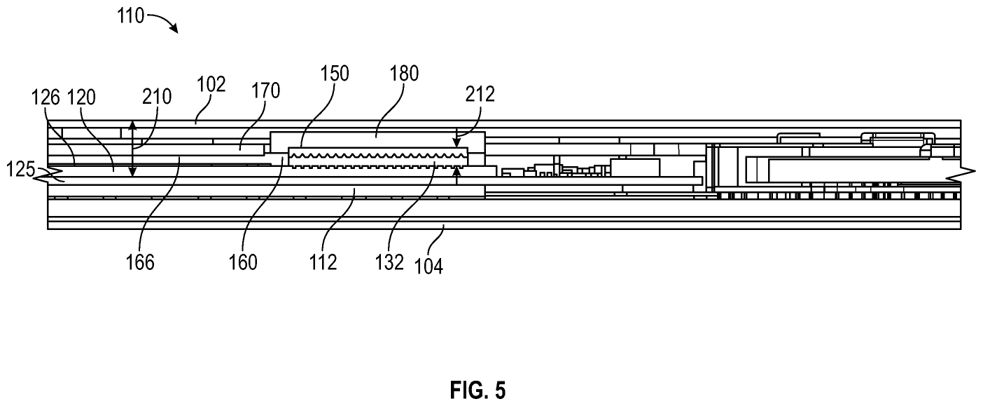

FIG. 5 illustrates a cross section of the electronic system 110. The upper surface of the cross section is the D cover 102, or the bottom outer surface of a laptop. The lower surface of the cross section is the C cover 104, or the top outer surface of the lower portion of a laptop, for example where a keyboard is located. In an example the z height, or depth, from the D cover 102 to the C cover 104 can be about one centimeter. In an example, the z height, or depth, from the D cover 102 to the C cover 104 can be more than one centimeter. In another example, the z height, or depth from the D cover 102 to the C cover 104 can be less than one centimeter. The distance from the D cover 102 to the C cover 104 can be any depth which is sufficient to house the internal components of a computer system.

In an example, a first z height 210 from the printed circuit board (PCB) 125 to the D cover 102 is between four millimeters to five millimeters. In an example, the first z height 210 is approximately four and a half millimeters. In another example, the first z height 210 is approximately 4.65 millimeters. In an example a second z height 212 as a distance from the memory socket 132 to the top of the removable memory package 150 is between two and three millimeters. In another example, the second z height 212 is approximately two and half millimeters. In another example, the second z height 212 is approximately 2.88 millimeters.

As illustrated in FIG. 5, the removable memory package 150 is connected with the memory socket 132 on the package 120. The package 120 also supports a die, or SoC, 126 proximate to the removable memory package 150. The removable memory package 150 and the SoC 126 are on the same package allowing the distance between the removable memory package 150 and the SoC 126 to be decreased. This arrangement can minimize complex circuitry or routing between the removable memory package 150 and the SoC 126. This arrangement can also increase the memory speed during processing.

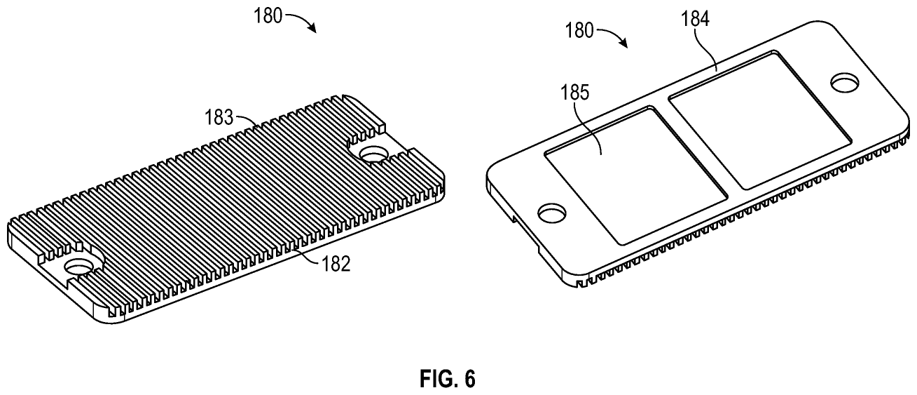

When memory is being processed, the electrical components of the memory can generate heat. The processing system can also generate heat. For a computer system including memory and a processor to operate efficiently, the heat should be removed or dispersed. In an example shown in FIG. 6 the load plate 180 can function as a cooling mechanism for the removable memory package 150 and the electronic system proximate to the removable memory package 150. The load plate 180 can be made from stainless steel, copper, aluminum or any material which provides cooling properties to the system. The load plate 180 can also have fins 183, grooves, indents or the like on an outer surface 182. The fins 183 provide a surface for air or other cooling fluid to pass through.

At least on insert 185 or material coupled to the inner surface are disposed on an inner surface 184 of the load plate 180. The at least one insert 185 can be made from copper or aluminum or the like. The at least one insert 185 can also be made from any material which provides heat dissipation. The at least one insert can be a thermal interface material (TIM) to aid in the thermal management of the removable memory package 150. In an example using a metal TIM, the TIM provides for higher thermal conductivity in the system. The at least one insert 185 is coupled with the inner surface 184 of the load plate 180 on an area corresponding to the removable memory package 150.

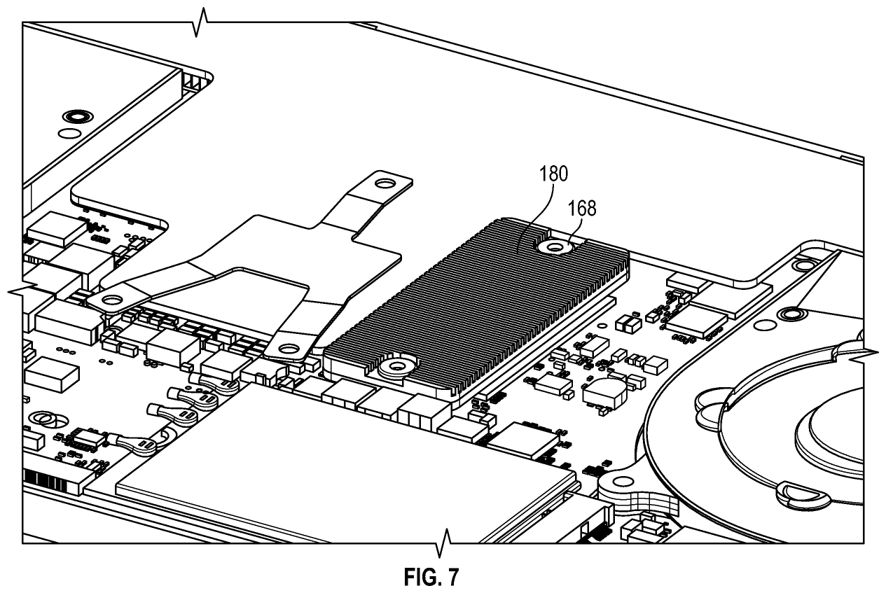

The load plate 180, as illustrated in FIG. 7, is coupled to the support plate 160 with the at least one fastener 168. In an example, there are two fasteners 168 on opposing sides of the support plate 160 and load plate 180. The at least one fastener 168 can apply a total load of between approximately 150N and approximately 200N to the load plate 180. In another example, the at least one fastener 168 can apply a total load of between approximately 175N and approximately 200N. In another example, the at least one fastener 168 can apply a total load of approximately 190N to the load plate. The desired load applied to the load plate 180 is determined by the total load necessary to couple the removable memory package 150 with the at least one slot 162 and then with the memory socket footprint 130.

In an example where a load is applied to the load plate 180, an underfill can be applied under the package to offset some of the load applied. The underfill could be applied completely under the SoC. In another example, solder balls can be applied under the corners of the package.

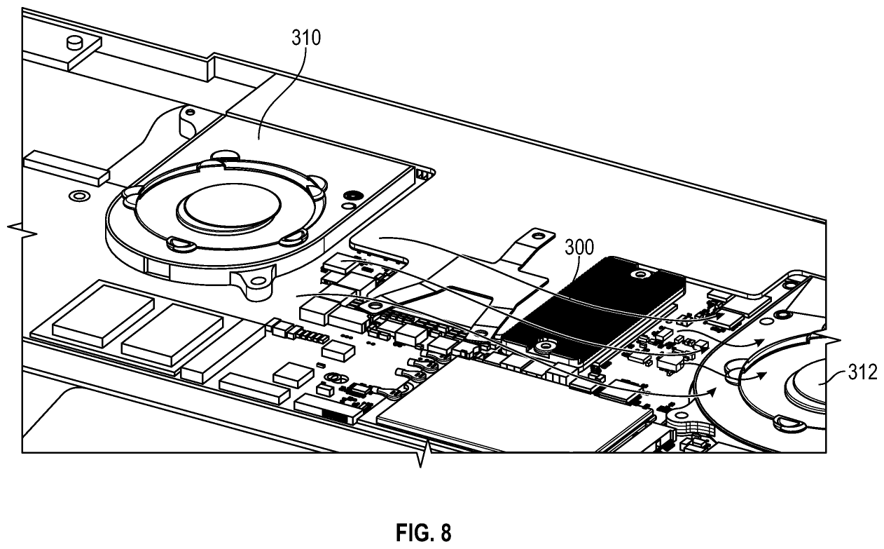

As illustrated in FIG. 8, the electronic system 110 is cooled by passing forced air 300 passing over or around the load plate 180. The forced air 300 can be supplied by, for example, a first fan 310, passing through the fins 183, and received by a second fan 312 on an opposing side of the electronic system 110 from the first fan 310. The first fan 310 generates cooling air which also passes over the vapor chamber 170 and is received by the second fan 312.

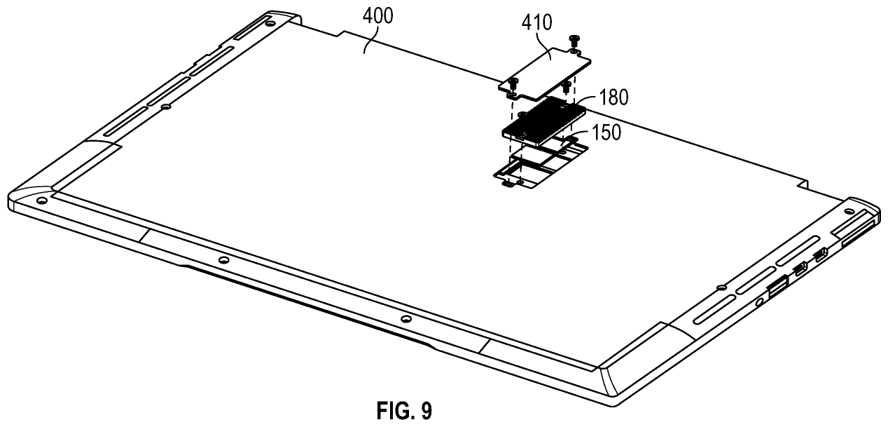

The computer system 100 including the electronic system 110 and the cooling elements including at least the first fan 310 and the second fan 312 and the vapor chamber 170 and the remaining components of the computer system are covered by the C cover 104 on one side and the D cover 102 on the other. As illustrated in the example shown in FIG. 9, the D cover 102 can include a removable cover 410. The removable cover 410 is located at a position which provides a user access to the modular memory component 400, including, for example, the load plate 180, the at least one removable memory package 150. In this example, the at least one removable memory package 150 is supported in a removable arrangement in the support plate 160.

A user would gain access to the removable at least one removable memory package 150 by detaching the removable cover 410. The removable cover 410 can be coupled with the D cover 102 with fasteners, locking mechanism, latches, interference fits or the like. The user would then decouple the load plate 180 from the support plate 160 by removing the at least one fastener 168. For example, a fastener can be a screw which, when tightened applies the desired load to the load plate and thereby to the removable memory package 150 and memory socket 132. The user could then remove the load plate 180 from the modular memory component 400 and thereby gain access to the removable memory package 150 supported by the support plate 160. Once the load plate 180 is removed, a user would remove the removable memory package 150 from its location in the support plate. The user could then replace the removable memory package 150 with a new memory package.

To replace the removable memory package 150 with a new memory package, the user would align the new memory package in the appropriate location on the support plate 160. Aligning the new memory package would also align the memory package with a predetermined memory socket on the package. The user could apply some pressure to the new memory package to more completely couple the new memory package with the predetermined memory socket. The user, in this example, would then replace the load plate such that the load plate covers the newly installed memory package and the support plate. The user would then couple the load plate with the support plate with the same fasteners which were originally removed. When coupling the load plate, the user would couple the fasteners such that a predetermined load was applied to the load plate and thereby the memory package. The user would then reattach the removable cover to the D cover such that the removable cover is secured in place. In this example, the user would not have to remove the entire D cover from the computer to gain access to the modular memory component. Instead, only a small cover could be removed to gain access to a specific part of the computer system where the modular memory component is located.

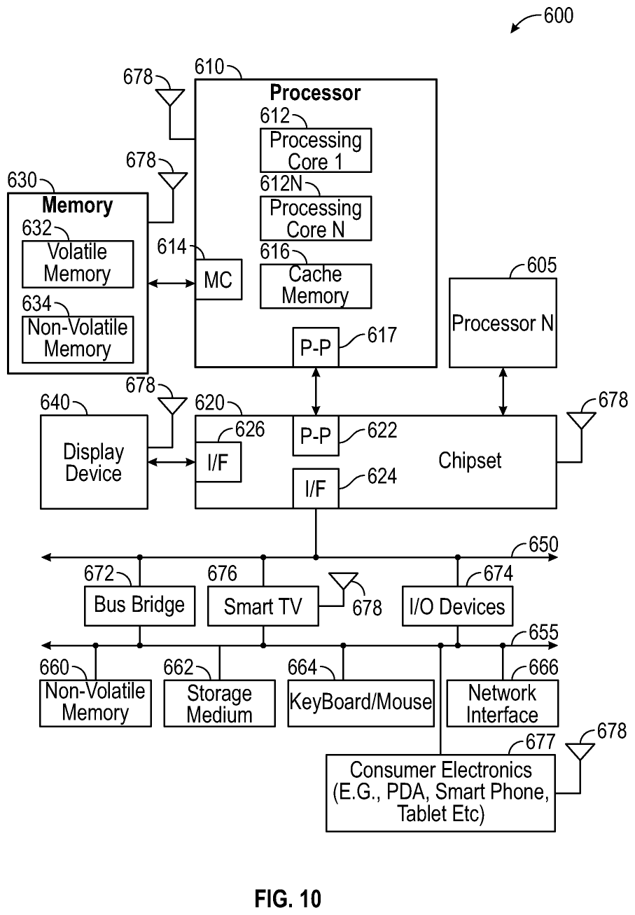

FIG. 10 illustrates a system level diagram, depicting an example of a computer system (e.g., system) that may include the electronic system and modular memory component, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system. The system 600 includes the modular memory component and the removable cover whereby a user can access the modular memory component.

In one embodiment, a processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes the modular memory component 632 which is a volatile memory and/or a non-volatile memory 634. In some embodiments, processor 610 is coupled with the memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, modular memory component 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 through the modular memory component 632 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include a modular memory component with a support plate with an upper side, a lower side, and at least one slot, wherein the support plate is coupled to a package having a memory socket footprint. A memory socket is coupled to the package on the memory socket footprint, wherein the support plate sandwiches the memory socket on the memory socket footprint and wherein the at least one slot exposes the memory socket. At least one removable memory component is disposed within the at least one slot, where the at least one removable memory component is connected to the memory socket at the at least one slot. The modular memory component can also include a load plate with a heat sink on a lower surface and at least one coupling area where the at least one coupling area is aligned with the memory socket and the load plate is coupled to a top surface of the support plate and where the support plate and the load plate are coupled at the memory socket footprint on the package.

Aspect 2 can include, or can optionally be combined with the subject matter of Aspect 1, where the memory socket area includes a memory footprint on the substrate and a memory socket. The memory socket can include at least one alignment pin on the package and proximate to the memory footprint which can align the memory socket with the memory footprint. The memory socket can also be coupled with the memory footprint.

Aspect 3 can include, or can optionally be combined with the subject matter of Aspect 1, where the modular memory a vapor chamber proximate to the support plate.

Aspect 4 can include, or can optionally be combined with the subject matter of claim 1, where the support plate is attached to a vapor chamber.

Aspect 5 can include, or can optionally be combined with the subject matter of claim 1 wherein the heat sink is a copper insert.

Aspect 6 can include, or can optionally be combined with the subject matter of Aspect 1 where the load plate includes a plurality of fins on an upper surface of the load plate.

Aspect 7 can include, or can optionally be combined with the subject matter of Aspect 1, further comprising at least one fastener which couples which couples the support plate with the substrate and the cooling plate with the substrate at the attachment area.

Aspect 8 can include an electronic system with a heat spreader, a substrate with a socketed memory area engaged with the heat spreader, a system on a chip fixed to the substrate, at least one alignment member proximate to the socketed memory area, a support plate with at least one opening, at least one alignment coupling, and a thermal dispersion component. Further, the support plate is aligned with the socketed memory area such that the at least one opening is configured to align with the socketed memory area, and at least one removable memory component supported in the at least one opening and coupled with the socketed memory area through the at least one opening. The electronic system can also include a heat transfer interface removably coupled with the support plate and covering the at least one removable memory component.

Aspect 9 can include, or can optionally be combined with the subject matter of Aspect 8, where the system is a component of a portable personal computer.

Aspect 10 can include, or can optionally be combined with the subject matter of Aspect 8 where the wherein the socketed memory area can include a memory footprint on a substrate a memory socket coupled with the memory footprint.

Aspect 11 can include, or can optionally be combined with the subject matter of Aspect 8 where the removable memory component is RAM.

Aspect 12 can include, or can optionally be combined with the subject matter of claim 9 where the RAM is proximate to a processor on the substrate.

Aspect 13 can include, or can optionally be combined with the subject matter of claim 8, where the removable memory component is adjacent to the processor.

Aspect 14 can include, or can optionally be combined with the subject matter of claim 8, where the heat transfer interface is a vapor chamber and the vapor chamber is proximate to a fan.

Aspect 15 can include, or can optionally be combined with the subject matter of claim 8, where the heat transfer interface is a heat sink proximate to a fan.

Aspect 16 can include, or can optionally be combined with the subject matter of claim 8, further comprising the support plate has two openings and two removable memory packages.

Aspect 17 can include method of replacing a memory component in a system including the steps of removing a cover at a designated location on a computer; decoupling a cooling plate from a support plate; removing at least one memory component from the support plate; aligning at least one new memory component with a predetermined socket area on a substrate where the socket area is accessible through an opening in the support plate; coupling the at least one new memory component with the predetermined socket area; placing the cooling plate on top of the at least one new memory component; coupling the cooling plate with the support plate; and placing and securing the cover in the designated location on a computer.

Aspect 18 can include, or can optionally be combined with the subject matter of claim 16 where the computer is a portable personal computer.

Aspect 19 can include, or can optionally be combined with the subject matter of claim 17 where the predetermined socket area is on a substrate having a system on chip.

Aspect 20 can include, or can optionally be combined with the subject matter of claim 18 where the socket area includes a memory footprint on a substrate; and a memory socket aligned with the memory footprint where the memory socket is aligned with the memory footprint with at least one alignment coupling.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A modular memory component comprising:
a support plate with an upper side, a lower side, and at least one slot;
wherein the support plate is coupled to a package having a memory socket footprint;
a memory socket coupled to the package on the memory socket footprint;
wherein the support plate sandwiches the memory socket on the memory socket footprint;
wherein the at least one slot exposes the memory socket;
at least one removable memory component disposed within the at least one slot; and
wherein the at least one removable memory component is connected to the memory socket at the at least one slot;
a load plate with a heat sink on a lower surface and at least one coupling area;
wherein the at least one coupling area is aligned with the memory socket;
wherein the load plate is coupled to a top surface of the support plate; and
wherein the support plate and the load plate are coupled at the memory socket footprint on the substrate.

2. The modular memory component of claim 1, wherein the substrate includes:
the memory socket footprint;
the memory socket;
wherein at least one alignment pin on to the package and proximate to the memory socket footprint aligns the memory socket with the memory socket footprint; and
wherein the memory socket is coupled with the substrate.

3. The modular memory component of claim 1, further comprising a vapor chamber proximate to the support plate.

4. The modular memory component of claim 1, wherein the support plate is attached to a vapor chamber.

5. The modular memory component of claim 1, wherein the heat sink is a copper insert.

6. The modular memory component of claim 1, wherein the load plate includes a plurality of fins on an upper surface of the load plate.

7. The modular memory component of claim 1, further comprising at least one fastener coupling the support plate with the substrate and the load plate with the substrate.

8. An electronic system comprising:
a heat spreader;
a substrate with a socketed memory area engaged with the heat spreader;
a system on a chip fixed to the substrate;
at least one alignment member proximate to the socketed memory area;
a support plate with at least one opening, at least one alignment coupling, and a thermal dispersion component;
wherein the support plate is aligned with the socketed memory area such that the at least one opening is configured to align with the socketed memory area;
at least one removable memory package supported in the at least one opening and coupled with the socketed memory area through the at least one opening; and
a heat transfer interface removably coupled with the support plate and covering the at least one removable memory package.

9. The electronic system of claim 8, wherein the system is a component of a portable personal computer.

10. The electronic system of claim 8, wherein the socketed memory area includes:
a memory footprint on a substrate; and
a memory socket coupled with the memory footprint.

11. The electronic system of claim 8, wherein the removable memory package is RAM.

12. The electronic system of claim 11, wherein the RAM is proximate to a processor on the substrate.

13. The electronic system of claim 8 wherein the removable memory package is adjacent to a processor.

14. The electronic system of claim 8, wherein the heat transfer interface is a vapor chamber;
wherein the vapor chamber is proximate to a fan.

15. The electronic system of claim 8, wherein the heat transfer interface is a heat sink proximate to a fan.

16. The electronic system of claim 8, further comprising:
the support plate with two openings; and
two removable memory packages.

17. A method of replacing a memory component in a system:
removing a cover at a designated location on a computer;
decoupling a load plate from a support plate;
removing a removable memory package from the support plate;
aligning a new removable memory package with a memory socket on a substrate;
wherein the memory socket is accessible through an opening in the support plate;
coupling the new removable memory package with the memory socket;
placing the load plate on top of the new removable memory package;
coupling the load plate with the support plate; and
placing and securing the cover in the designated location on a computer.

18. The method of claim 17, wherein the computer is a portable personal computer.

19. The method of claim 17, wherein the memory socket is on a substrate having a system on chip.

20. The method of claim 18 wherein the memory socket includes:
a memory footprint on a substrate; and
a memory socket aligned with the memory footprint;
wherein the memory socket is aligned with the memory footprint with at least one alignment coupling.
